(19) United States
(12) Patent Application Publication
(10) Pub. No.: US 2024/0341049 A1
(43) Pub. Date: Oct. 10, 2024

(54) VIBRATION ASSEMBLY

(71) Applicant: AAC Acoustic Technologies (Shanghai) Co., Ltd., Shanghai (CN)

(72) Inventors: Lijin Zhang, Shanghai (CN); Xiuyue Wang, Shanghai (CN)

(21) Appl. No.: 18/398,208

(22) Filed: Dec. 28, 2023

Related U.S. Application Data
(63) Continuation of application No. PCT/CN2023/087363, filed on Apr. 10, 2023.

(51) Int. Cl. H05K 7/12; B06B 1/02

(52) U.S. Cl. CPC H05K 7/12; B06B 1/02

(57) ABSTRACT

A vibration assembly includes a fixing member, a bearing member elastically connected to the fixing member, a functional component fixed to the bearing member, and a driving unit fixed to the functional component. The fixing member includes an annular frame with a hollow cavity, at least three spaced cantilever beams, a soft elastic block, and two fixed end beams. The fixed end beam has two ends fixedly connected to the inner side of the annular frame and a middle portion forming a gap with the annular frame. The bearing member is received in the hollow cavity and has two ends respectively fixed to the middle portions of the two fixed end beams. Through the solution, sufficient vibration and uniform acceleration distribution can be realized in the case of vibration in a specific direction, while vibration intensity in other directions is weak, thereby bringing good vibration experience.

### CROSS-REFERENCE TO RELATED APPLICATIONS

This application is a continuation of International Application No. PCT/CN2023/087363, filed on Apr. 10, 2023, which is hereby incorporated by reference in its entirety.

### TECHNICAL FIELD

The present disclosure belongs to the field of tactile feedback technologies, and in particular, to a vibration assembly.

### BACKGROUND

With the growing of the electronic technology industry, electronic products are playing an increasingly important role in human daily life, and people are increasingly dependent on functionality of various electronic products. The so-called “dependent on functionality” includes, but is not limited to, hearing, vision, smell, touch, and the like. However, touch mainly emphasizes users' requirements for vibration experience that the users are increasingly dependent on during use of emerging electronic products. Both electronic entertainment products and electronic work products involve a large number of tactile requirements for different vibration degrees and different vibration modes. A touchpad is an electronic device based on a touch force of a finger and swiping thereon to move a cursor. The touchpad may be used for subsequent game product development as well as used as a daily work device.

At present, the users have put forward more and more stringent requirements for vibration of the touch pad. For example, on the basis of meeting a compact assembly condition and not affecting other non-touch functions, directional vibration of a touch screen in a specific degree of freedom direction is achieved while vibration in other degrees of freedom is limited as much as possible, and the directional vibration is required to meet vibration experience required by the users at the same time. A good degree of the vibration experience is generally measured by uniformity and magnitude of distribution of acceleration. However, currently, there is still a lack of touchpad vibration structure designs on the market that can meet the above tactile characteristics.

### SUMMARY

An objective of the present disclosure is to provide a vibration assembly, which can realize directional vibration of a functional component in one direction while vibration intensity in other directions is weak, and has sufficient vibration and uniform acceleration distribution in the direction of directional vibration.

The technical solution of the present disclosure is as follows. A vibration assembly is provided, including: a fixing member for fixing and supporting, a bearing member elastically connected to the fixing member, a functional component fixed to the bearing member, and a driving unit fixed to the functional component, wherein the fixing member includes an annular frame with a hollow cavity formed inside, at least three spaced cantilever beams extending from an inner side of the annular frame towards the hollow cavity, a soft elastic block fixed between the cantilever beam and the functional component, and two fixed end beams symmetrically distributed on two opposite sides of the hollow cavity, each of the fixed end beams have two ends fixedly connected to the inner side of the annular frame and a middle portion forming a gap with the annular frame, the two fixed end beams are parallel to each other, and the bearing member is received in the hollow cavity and has two ends respectively fixed to the middle portions of the two fixed end beams.

In an embodiment, one of the two fixed end beams includes two fixed protrusions protruding and spaced apart from the inner side of the annular frame and an elastic beam connected between the two fixed protrusions, and an end portion of the bearing member is fixed to a side of the elastic beam away from the annular frame.

In an embodiment, the elastic beam protrudes from a plate surface of the annular frame and has a cross-sectional area gradually reducing in a protruding direction, and the end portion of the bearing member is fixed to a protruding end of the elastic beam.

In an embodiment, the bearing member includes a retaining portion located in the middle and connecting feet connected to two opposite sides of the retaining portion. The two connecting feet are respectively fixed to the two fixed end beams.

In an embodiment, the retaining portion is close to a long side of the annular frame and located in the middle, the two connecting feet are respectively fixed to two diagonal corners of the retaining portion, and the connecting feet bend and extend along an inner edge of the annular frame.

In an embodiment, the retaining portion is provided with an avoiding opening, and the driving unit is accommodated in the avoiding opening.

In an embodiment, the hollow cavity is in a shape of a rectangle, both the fixed end beams and the cantilever beams are located on a short side of the hollow cavity, and four cantilever beams are provided and respectively located at four corners of the hollow cavity.

In an embodiment, each of the cantilever beams bends towards a side of the annular frame to protrude from the plate surface of the annular frame, the soft elastic block is fixed to an end portion of a protruding side of the cantilever beam, and the soft elastic block is made of a silicone or rubber material.

In an embodiment, the annular frame is provided with assembling holes spaced from one another.

In an embodiment, the functional component includes a touch-screen module and/or a printed circuit board (PCB) module.

The present disclosure has the following beneficial effects. The annular frame may be fixed to an electronic terminal, such as a middle frame, a surface frame, or the like. The two ends of the bearing member are respectively fixed to the two fixed end beams. The two fixed end beams are parallel to each other, and each of the fixed end beams has two ends fixedly connected to the inner side of the annular frame and a middle portion forming a gap with the annular frame. Therefore, the bearing member can be displaced in a direction perpendicular to the fixed end beam. The functional component is fixed to the bearing member, and the soft elastic block is fixed between the functional component and the cantilever beam, and the soft elastic block can realize a shearing force of the functional component moving in a plane and provide a support force in a thickness direction. Therefore, when the driving unit drives the functional component to vibrate in a plane in a direction perpendicular to the fixed end beam, sufficient vibration and uniform acceleration distribution can be realized, while vibration intensity in other directions is weak, thereby bringing good vibration experience.

### BRIEF DESCRIPTION OF DRAWINGS

FIG. 1 is a schematic diagram of an overall structure of a vibration assembly from a first perspective according to the present disclosure;

FIG. 2 is a schematic diagram of the overall structure of the vibration assembly from a second perspective according to the present disclosure;

FIG. 3 is a schematic diagram of a three-dimensional structure after partial removal from the vibration assembly according to the present disclosure;

FIG. 4 is a schematic diagram of a three-dimensional exploded structure of the vibration assembly according to the present disclosure; and

FIG. 5 is a schematic diagram of acceleration distribution of the vibration assembly in a vibration mode according to the present disclosure.

### DESCRIPTION OF EMBODIMENTS

The present disclosure is further described below with reference to the accompanying drawings and embodiments.

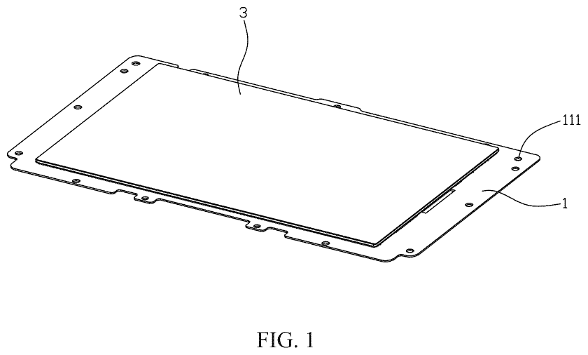

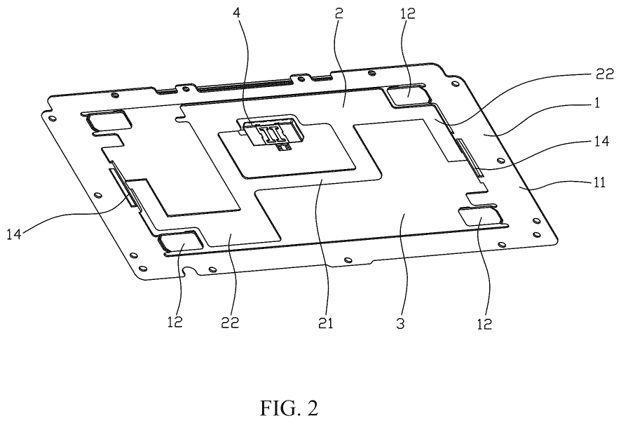

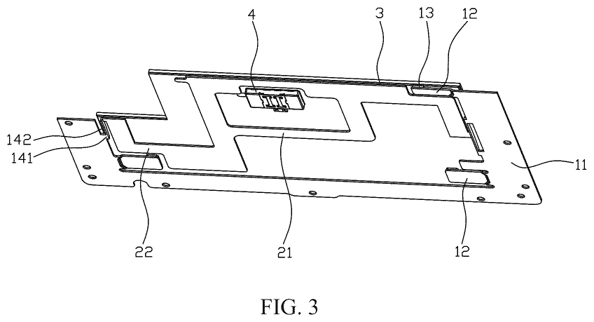

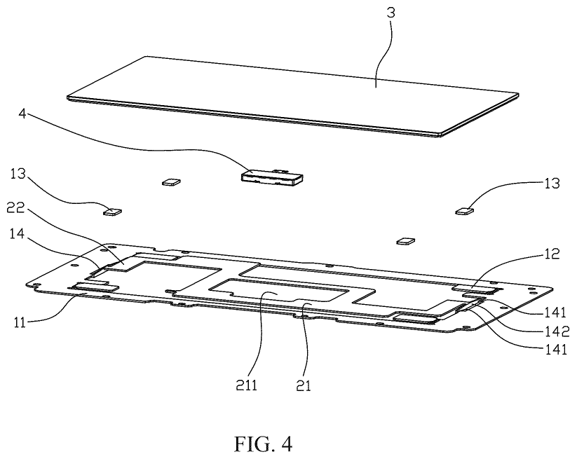

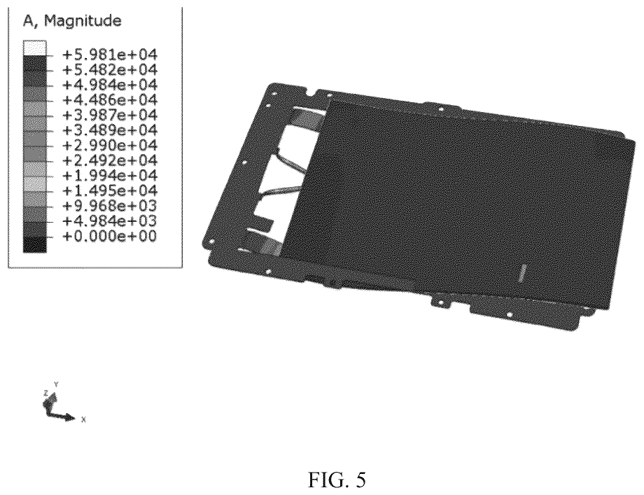

Referring to FIG. 1 to FIG. 5, a vibration assembly is provided, including a fixing member 1 for fixing and supporting, a bearing member 2 elastically connected to the fixing member 1, a functional component 3 fixed to the bearing member 2, and a driving unit 4 fixed to the functional component 3. The fixing member 1 includes an annular frame 11 with a hollow cavity formed inside, at least three spaced cantilever beams 12 extending from an inner side of the annular frame 11 towards the hollow cavity, a soft elastic block 13 fixed between the cantilever beam 12 and the functional component 3, and two fixed end beams 14 symmetrically distributed on two opposite sides of the hollow cavity. Each of the fixed end beams 14 has two ends fixedly connected to the inner side of the annular frame 11 and a middle portion forming a gap with the annular frame 11. The two fixed end beams 14 are parallel to each other. The bearing member 2 is received in the hollow cavity and has two ends respectively fixed to the middle portions of the two fixed end beams 14.

The annular frame 11 may be fixed to an electronic terminal, such as a middle frame, a surface frame, or the like. The two ends of the bearing member 2 are respectively fixed to the two fixed end beams 14. The two fixed end beams 14 are parallel to each other, and each of the fixed end beams 14 has two ends fixedly connected to the inner side of the annular frame 11 and a middle portion forming a gap with the annular frame 11. Therefore, the bearing member 2 can be displaced in a direction perpendicular to the fixed end beam 14. The functional component 3 is fixed to the bearing member 2, and the soft elastic block 13 is fixed between the functional component 3 and the cantilever beam 12, and the soft elastic block 13 can realize a shearing force of the functional component 3 moving in a plane and provide a support force in a thickness direction. Therefore, when the driving unit 4 drives the functional component 3 to vibrate in a plane in a direction perpendicular to the fixed end beam 14, sufficient vibration and uniform acceleration distribution can be realized, while vibration intensity in other directions is weak, thereby bringing good vibration experience.

In an embodiment, each of the fixed end beams 14 includes two fixed protrusions 141 protruding and spaced apart from the inner side of the annular frame 11 and an elastic beam 142 connected between the two fixed protrusions 141, and an end portion of the bearing member 2 is fixed to a side of the elastic beam 142 away from the annular frame 11. The elastic beam 142 protrudes from a plate surface of the annular frame 11 and has a cross-sectional area gradually reducing in a protruding direction, and the end portion of the bearing member 2 is fixed to a protruding end of the elastic beam 142.

In an embodiment, the annular frame 11 is in a shape of a rectangular ring and a plate as a whole, and the hollow cavity is in a shape of a rectangle. The fixed end beam 14 is located inside a wide side of the annular frame 11. The two fixed protrusions 141 are symmetrically arranged. Two ends of the elastic beam 142 are respectively fixed to corresponding end portions of the two fixed protrusions 141. Therefore, a gap is formed between the elastic beam 142 and the inner side of the annular frame 11, and the elastic beam 142 can vibrate in a direction perpendicular to the elastic beam 142 on the plate surface of the annular frame 11, and is suppressed from vibrating in a direction parallel to the elastic beam 142. In addition, the elastic beam 142 protrudes from the plate surface of the annular frame 11, and the protruding side is in a shape of an isosceles trapezoid. The elastic beam 142 is less likely to vibrate in a direction perpendicular to the plate surface of the annular frame 11. Moreover, the end portion of the bearing member 2 is fixed to the protruding end of the elastic beam 142, that is, the bearing member 2 is located on one side of the annular frame 11 but not flush with the annular frame 11, and the functional component 3 is fixed on a side of the bearing member 2 away from the annular frame 11. In this way, a gap is formed among the functional component 3, the annular frame 11, and a component to which the annular frame 11 is fixed (such as the middle frame or a bottom case of the electronic terminal), so that no interference occurs and the vibration is more reliable.

In an embodiment, the bearing member 2 includes a retaining portion 21 located in the middle and connecting feet 22 connected to two opposite sides of the retaining portion 21, the two connecting feet 22 are respectively fixed to the two fixed end beams 14, and both the retaining portion 21 and the connecting feet 22 are bonded and fixed to one side of the functional component 3. In an embodiment, the retaining portion 21 is close to a long side of the annular frame 11 and located in the middle. That is, the retaining portion 21 deviates from a center in a width direction of the annular frame 11 and is located in the middle in a length direction. The two connecting feet 22 are respectively fixed to two diagonal corners of the retaining portion 21, and the connecting feet 22 bend and extend along an inner edge of the annular frame 11. In this way, a hollow structure is formed between the bearing member 2 and the annular frame 11, which can reduce a weight and save material costs while supporting the functional component 3. Moreover, another component may be arranged in the hollow structure, which is conducive to improving space utilization of the electronic terminal.

In an embodiment, the retaining portion 21 is provided with an avoiding opening 211, and the driving unit 4 is accommodated in the avoiding opening 211. The functional component 3 includes a touch-screen module and/or a PCB module. In this embodiment, the functional component 3 includes a touch-screen module and a PCB module integrally fixed, a control circuit may be integrated onto the PCB module, the touch-screen module is electrically connected to the PCB module, a driving motor is used as the driving unit 4, and the driving unit 4 is fixed and electrically connected to the PCB module and is located in the avoiding opening 211. In this way, when the touch-screen module receives a trigger signal, the PCB module may convert a touch mechanical signal into a corresponding voltage signal, and then feed the voltage signal back to the driving unit 4 after being operationally amplified. The driving unit 4 performs servo driving on the touch-screen module in a specific frequency range and peak according to a built-in force-to-electricity conversion law, so that the touch screen can achieve a vibration experience requirement under the action of the driving unit 4. In some embodiments, the functional component 3 may be adaptively selected, such as a microphone, a light sensor, or the like.

In an embodiment, the cantilever beams 12 are located on a short side of the hollow cavity, and four cantilever beams 12 are provided and respectively located at four corners of the hollow cavity. The connecting feet 22 may be provided with notches used to accommodate the corresponding cantilever beams 12 to realize avoidance. In an embodiment, each of the cantilever beams 12 bends towards a side of the annular frame 11 to protrude from the plate surface of the annular frame 11, the soft elastic block 13 is fixed to an end portion of a protruding side of the cantilever beam 12, and the soft elastic block 13 is made of a silicone or rubber material. The soft elastic block 13 may be fixed to the cantilever beam 12 and the functional component 3 by bonding. In this way, four soft elastic blocks 13 play a role in flexibly supporting the functional component 3, and hyperelasticity of the soft elastic blocks 13 can be used to provide a lateral shearing force to achieve horizontal reciprocating movement of the supported functional component 3.

In an embodiment, the annular frame 11 is provided with assembling holes 111 spaced from one another. The annular frame 11 may be fixedly connected to the middle frame and a base of the electronic terminal through the assembling holes 111 of a fastener such as a screw, thereby realizing a fixed connection of the functional component 3.

The vibration assembly in this solution can meet stiffness requirements in a thickness direction and a longitudinal direction, and can also meet a vibration requirement in a transverse direction of a touch module. Moreover, the touch module has a high-quality mode with horizontal movement tendency and good vibration.

The above are merely embodiments of the present disclosure. It should be noted herein that, for those skilled in the art, improvements can be made without departing from the creative concept of the present disclosure, but these all fall within the protection scope of the present disclosure.

What is claimed is:

1. A vibration assembly, comprising:
a fixing member for fixing and supporting;
a bearing member elastically connected to the fixing member;
a functional component fixed to the bearing member; and
a driving unit fixed to the functional component,
wherein the fixing member comprises an annular frame with a hollow cavity formed inside, at least three spaced cantilever beams extending from an inner side of the annular frame towards the hollow cavity, a soft elastic block fixed between the cantilever beam and the functional component, and two fixed end beams symmetrically distributed on two opposite sides of the hollow cavity; and
wherein each of the fixed end beams have two ends fixedly connected to the inner side of the annular frame and a middle portion forming a gap with the annular frame, the two fixed end beams are parallel to each other, and the bearing member is received in the hollow cavity and has two ends respectively fixed to the middle portions of the two fixed end beams.

2. The vibration assembly as described in claim 1, wherein one of the two fixed end beams comprises two fixed protrusions protruding and spaced apart from the inner side of the annular frame, and an elastic beam connected between the two fixed protrusions, wherein an end portion of the bearing member is fixed to a side of the elastic beam away from the annular frame.

3. The vibration assembly as described in claim 2, wherein the elastic beam protrudes from a plate surface of the annular frame and has a cross-sectional area gradually reducing in a protruding direction, and the end portion of the bearing member is fixed to a protruding end of the elastic beam.

4. The vibration assembly as described in claim 1, wherein the bearing member comprises a retaining portion located in the middle and connecting feet connected to two opposite sides of the retaining portion, wherein the two connecting feet are respectively fixed to the two fixed end beams.

5. The vibration assembly as described in claim 4, wherein the retaining portion is close to a long side of the annular frame and located in the middle, the two connecting feet are respectively fixed to two diagonal corners of the retaining portion, and the connecting feet bend and extend along an inner edge of the annular frame.

6. The vibration assembly as described in claim 4, wherein the retaining portion is provided with an avoiding opening, and the driving unit is accommodated in the avoiding opening.

7. The vibration assembly as described in claim 1, wherein the hollow cavity is in a shape of a rectangle, the fixed end beams and the cantilever beams are located on a short side of the hollow cavity, and four cantilever beams are provided and respectively located at four corners of the hollow cavity.

8. The vibration assembly as described in claim 7, wherein each of the cantilever beams bends towards a side of the annular frame to protrude from the plate surface of the annular frame, the soft elastic block is fixed to an end portion of a protruding side of one of the cantilever beams, and the soft elastic block is made of a silicone or rubber material.

9. The vibration assembly as described in claim 1, wherein the annular frame is provided with assembling holes spaced from one another.

10. The vibration assembly as described in claim 1, wherein the functional component comprises a touch-screen module and/or a printed circuit board (PCB) module.
